(19) United States
(12) Patent Application Publication
(10) Pub. No.: US 2024/0422963 A1
(43) Pub. Date: Dec. 19, 2024

(54) SEMICONDUCTOR MEMORY DEVICE

(71) Applicant: SAMSUNG ELECTRONICS CO., LTD., Suwon-si (KR)

(72) Inventors: KYO-SUK CHAE, Suwon-si (KR); Tai Uk Rim, Suwon-si (KR); Jin-seong Lee, Suwon-si (KR); Hee Jae Choi, Suwon-si (KR); Jung-Hoon Han, Suwon-si (KR); Byung Ha Kang, Suwon-si (KR); Gyu Taek Shin, Suwon-si (KR); Shin Woo Jeong, Suwon-si (KR)

(21) Appl. No.: 18/604,584

(22) Filed: Mar. 14, 2024

(30) Foreign Application Priority Data
Jun. 16, 2023 (KR) 10-2023-0077635

(51) Int. Cl. H10B 12/00

(52) U.S. Cl. CPC H10B 12/34; H10B 12/053

(57) ABSTRACT

A semiconductor memory device includes a substrate including a device isolation film defining active regions; and cell gate structures in trenches, including first areas and second areas, the cell gate structures extending to intersect the active regions, each of the cell gate structures includes a cell gate insulating layer, extending along inner sidewalls of the trenches, a first gate dielectric film, on sidewalls of the cell gate insulating layer, in a first area of the trench, a second gate dielectric film, on the sidewalls of the cell gate insulating layer, in a second area of the trench, and a cell gate electrode structure, including a first gate electrode layer on sidewalls of the first gate dielectric film and a second gate electrode layer on sidewalls of the second gate dielectric film in the second area.

### CROSS-REFERENCE TO RELATED APPLICATION

This application claims priority from Korean Patent Application No. 10-2023-0077635 filed on Jun. 16, 2023, in the Korean Intellectual Property Office, and all the benefits accruing therefrom under 35 U.S.C. 119, the contents of which in its entirety are herein incorporated by reference.

### BACKGROUND

### 1. Field

Embodiments relate to a semiconductor memory device.

### 2. Description of the Related Art

As semiconductor devices continue to advance in miniaturization, individual circuit patterns are becoming increasingly fine-tuned to accommodate more semiconductor components within the same area. As the integration density of devices, including buried channel array transistors (BCAT) grows, the pitch of multiple wordlines embedded in the substrates of the BCATs may gradually decrease.

### SUMMARY

The embodiments may be realized by providing a semiconductor memory device including a substrate including a device isolation film, which defines active regions; and cell gate structures in trenches, which include first areas in the substrate and second areas on the first areas, the cell gate structures extending to intersect the active regions, wherein each of the cell gate structures includes a cell gate insulating layer, which extends along inner sidewalls of its corresponding trenches, a first gate dielectric film, which is on sidewalls of the cell gate insulating layer, in a first area of the corresponding trench, a second gate dielectric film, which is on the sidewalls of the cell gate insulating layer, in a second area of the corresponding trench, and a cell gate electrode structure, which includes a first gate electrode layer on sidewalls of the first gate dielectric film in the first area of the corresponding trench and a second gate electrode layer on sidewalls of the second gate dielectric film in the second area of the corresponding trench, and in relation to the inner sidewalls of the corresponding trench, the second gate dielectric film has a greater thickness than the first gate dielectric film.

The embodiments may be realized by providing a semiconductor memory device including a substrate including a device isolation film, which defines active regions; and gate structures in trenches, which include first areas in the substrate and second areas on the first areas, the gate structures extending to intersect the active regions, wherein each of the gate structures includes a first gate insulating layer, which extends along sidewalls and a bottom surface of its corresponding trenches, a first gate dielectric film, which is on sidewalls of the first gate insulating layer, in a first area of the corresponding trench, a second gate dielectric film, which is on the sidewalls of the first gate insulating layer, in a second area of the corresponding trench, a barrier layer between the first and second gate dielectric films, a gate electrode structure, which includes a first gate electrode layer on sidewalls of the first gate dielectric film in the first area of the corresponding trench and a second gate electrode layer on sidewalls of the second gate dielectric film in the second area of the corresponding trench, and a capping film, which is on the second gate electrode layer, and the barrier layer is in contact with a bottom surface of the second gate dielectric film and a top surface of the first gate dielectric film.

The embodiments may be realized by providing a semiconductor memory device including a substrate including a device isolation film, which defines active regions; and gate structures in trenches, which include first areas in the substrate and second areas on the first areas, the gate structures extending to intersect the active regions, wherein each of the gate structures includes a first gate insulating layer, which extends along sidewalls and a bottom surface of its corresponding trenches, a first gate dielectric film, which is on sidewalls of the first gate insulating layer, in a first area of the corresponding trench, a second gate dielectric film, which is on the sidewalls of the first gate insulating layer, in a second area of the corresponding trench, a barrier layer between the first and second gate dielectric films, a gate electrode structure, which includes a first gate electrode layer on sidewalls of the first gate dielectric film in the first area of the corresponding trench and a second gate electrode layer on sidewalls of the second gate dielectric film in the second area of the corresponding trench, an inserted insulating layer, which is between the barrier layer and the second gate electrode layer, and a capping film, which is on the second gate electrode layer, and in relation to the sidewalls of the corresponding trench, the second gate dielectric film has a greater thickness than the first gate dielectric film.

### BRIEF DESCRIPTION OF THE DRAWINGS

Features will be apparent to those of skill in the art by describing in detail exemplary embodiments with reference to the attached drawings in which:

FIG. 1 is a layout view of a semiconductor memory device according to some embodiments of the present disclosure;

FIG. 2 is a layout view depicting only wordlines and active areas of FIG. 1;

FIG. 3 is a cross-sectional view taken along line A-A of FIG. 1;

FIG. 4 is a cross-sectional view taken along line B-B of FIG. 1;

FIG. 5 is a cross-sectional view taken along line C-C of FIG. 1;

FIG. 6 is a cross-sectional view taken along line D-D of FIG. 1;

FIG. 7 is an exemplary enlarged cross-sectional view of part P of FIG. 6;

FIGS. 8 through 11 are other exemplary enlarged cross-sectional views of part P of FIG. 6; and

FIGS. 12 through 18 are layout views or cross-sectional views of stages in a method of fabricating a semiconductor memory device according to some embodiments of the present disclosure.

### DETAILED DESCRIPTION

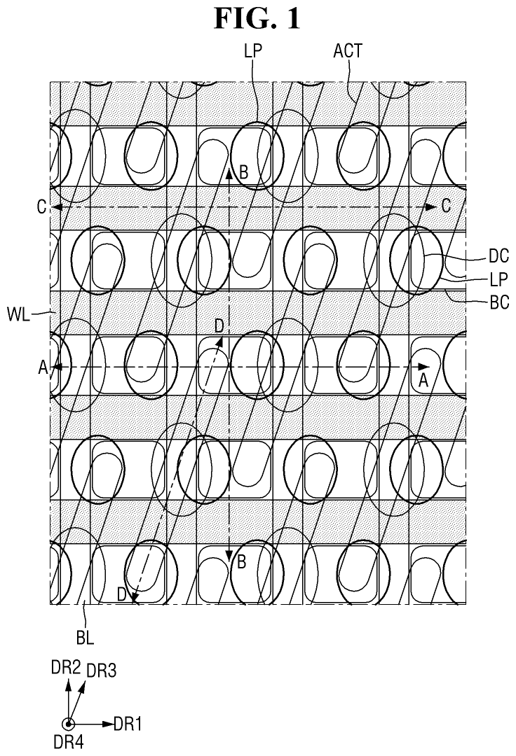

FIG. 1 is a layout view of a semiconductor memory device according to some

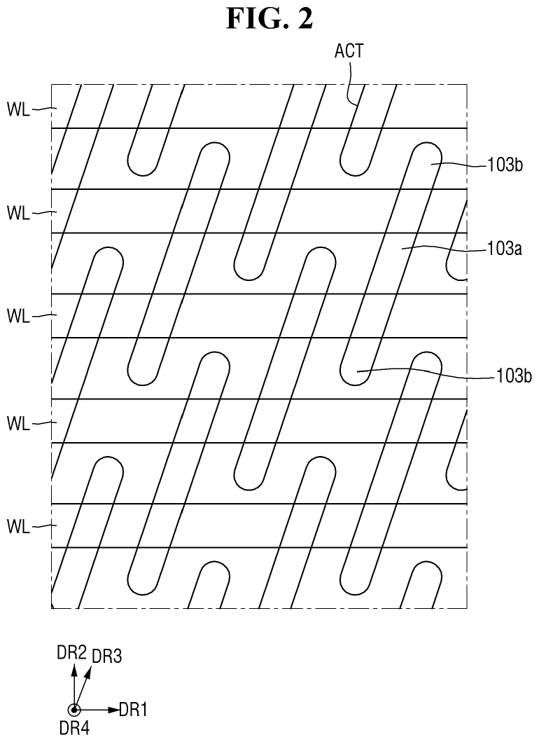

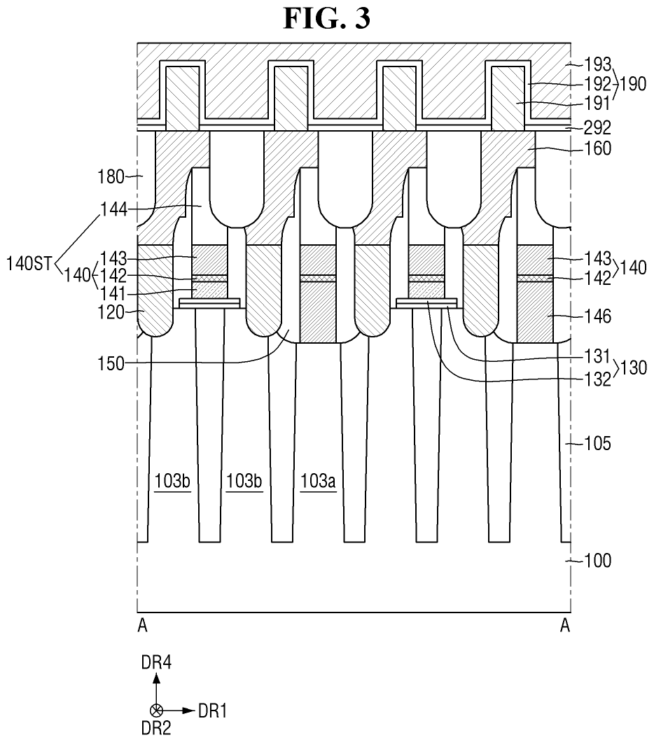

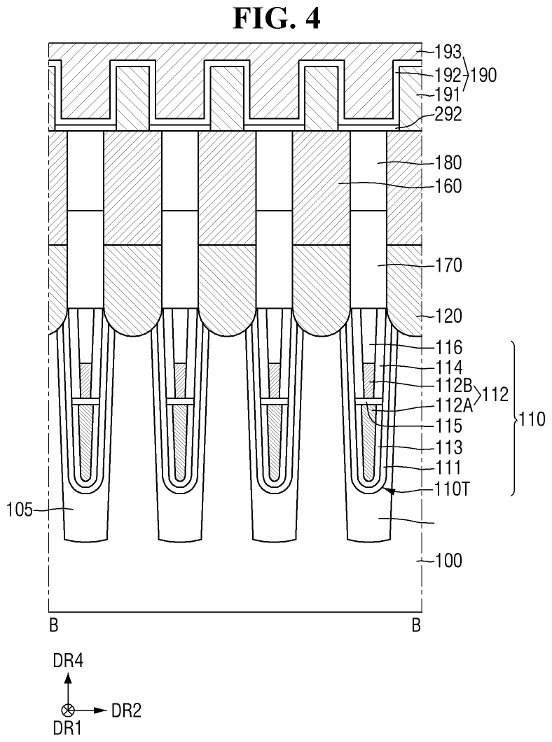

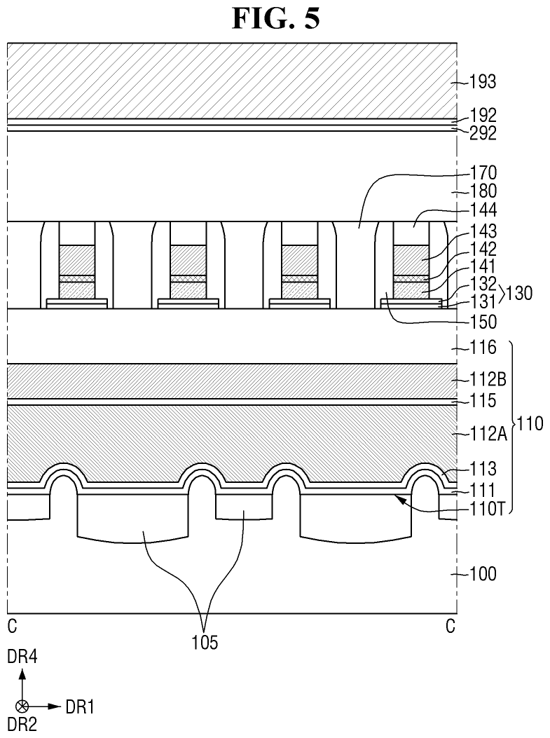

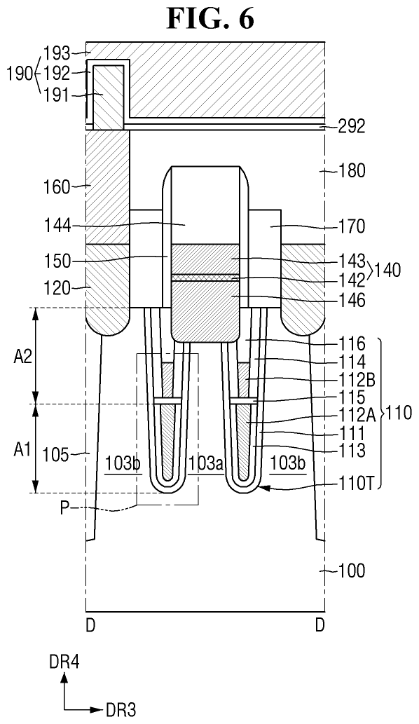

embodiments of the present disclosure. FIG. 2 is a layout view depicting only wordlines and active areas of FIG. 1. FIG. 3 is a cross-sectional view taken along line A-A of FIG. 1. FIG. 4 is a cross-sectional view taken along line B-B of FIG. 1. FIG. 5 is a cross-sectional view taken along line C-C of FIG. 1. FIG. 6 is a cross-sectional view taken along line D-D of FIG. 1.

The semiconductor memory device according to some embodiments of the present disclosure may be, e.g., a dynamic random access memory (DRAM) device.

Referring to FIGS. 1 and 2, the semiconductor memory device according to some embodiments of the present disclosure may include a plurality of cell active regions ACT.

The cell active regions ACT may be defined by a cell device isolation film 105. In accordance with a decrease in (e.g., a size of) the semiconductor memory device according to some embodiments of the present disclosure, the cell active regions ACT may be arranged as diagonal bars or oblique bars. For example, the cell active regions ACT may extend in a third direction DR3.

A plurality of gate electrodes, which extend in a first direction DR1 across the cell active regions ACT, may be arranged. The gate electrodes may extend in parallel to one another. The gate electrodes may be, e.g., wordlines WL. The wordlines WL may be arranged at equal intervals. The width of, or the spacing between, the wordlines WL may be determined by the design rule of the semiconductor memory device according to some embodiments of the present disclosure.

Each of the cell active regions ACT may be divided into three sections by two neighboring wordlines WL that extend in the first direction DR1. Each of the cell active regions ACT may include storage connection portions 103b and a bitline connection portion 103a. The bitline connection portion 103a may be positioned in the center of its corresponding cell active region ACT, and the storage connection portions 103b may be positioned at the ends of the corresponding cell active region ACT.

In an implementation, the bitline connection portion 103a may be part of the corresponding cell active region ACT that is connected to a bitline BL, and the storage connection portions 103b may be parts of the corresponding cell active region ACT that are connected to an information storage unit (“190” of FIG. 3). In an implementation, the bitline connection portion 103a may correspond to a common drain region, and the storage connection portions 103b may correspond to source regions. Each of the wordlines WL may form a transistor together with its neighboring bitline connection portion 103a and storage connection portion 103b.

A plurality of bitlines BL, which extend in a second direction DR2 that is perpendicular to the wordlines WL, may be on the wordlines WL. The bitlines BL may extend in parallel to one another. The bitlines BL may be arranged at equal intervals. The width of, and the spacing between, the bitlines BL may be determined by the design rule of the semiconductor memory device according to some embodiments of the present disclosure.

A fourth direction DR4 may be perpendicular to the first, second, and third directions DR1, DR2, and DR3. The fourth direction DR4 may correspond to the thickness direction of a substrate 100.

The semiconductor memory device according to some embodiments of the present disclosure may include various contact arrays on the cell active regions ACT. The contact arrays may include, e.g., direct contacts DC, buried contacts BC, or landing pads LP.

The direct contacts DC may refer to contacts that electrically connect the cell active regions ACT to the bitlines BL. The buried contacts BC may refer to contacts that connect the cell active regions ACT to lower electrodes (“191” of FIG. 3). The contact area between the buried contacts BC and the cell active regions ACT may be relatively small. In order to increase the contact area with the cell active regions ACT and the contact area with the lower electrodes 191, conductive landing pads LP may be provided.

The landing pads LP may be between the cell active regions ACT and the buried contacts BC. In an implementation, the landing pads LP may be between the buried contacts BC and the lower electrodes 191. The landing pads LP may increase the contact area with the cell active regions ACT and the contact area with the lower electrodes 191, and the contact resistance between the cell active regions Act and the lower electrodes 191 may be reduced.

The direct contacts DC may be connected to the bitline connection portions 103a of the cell active regions ACT. The buried contacts BC may be connected to the storage connection portions 103b of the cell active regions ACT. The buried contacts BC may be positioned near the respective ends of the cell active regions ACT, and the landing pads LP may partially overlap with the buried contacts BC, near the respective ends of each of the cell active regions ACT. In an implementation, the buried contacts BC may overlap with the cell active regions ACT and the cell device isolation film 105, between the wordlines WL and between the bitlines BL.

The wordlines WL may be buried within the substrate 100. The wordlines WL may extend across the cell active regions ACT, either between the direct contacts DC or between the buried contacts BC. Two wordlines WL may extend across a single cell active region ACT. The cell active regions ACT may extend in the third direction DR3, and the wordlines WL may form an angle of less than 90 degrees with the cell active regions ACT.

The direct contacts DC and the buried contacts BC may be symmetrically arranged with each other. The direct contacts DC and the buried contacts BC may be arranged in straight lines along the first and second directions DR1 and DR2. The landing pads LP, unlike the direct contacts DC and the buried contacts BC, may be arranged in a zigzag pattern along the second direction DR2, which corresponds to the extension direction of the bitlines BL, i.e., in the second direction DR2. The landing pads LP may overlap with the same sides of their respective bitlines BL in the first direction DR1, which corresponds to the extension direction of the wordlines WL.

In an implementation, in a first row, the landing pads LP may overlap with the left sides of their respective bitlines BL, while in a second row, the landing pads LP may overlap with the right sides of their respective bitlines BL.

Referring to FIGS. 1 through 7, the semiconductor memory device according to some embodiments of the present disclosure may include a plurality of cell gate structures 110, a plurality of bitline structures 140ST, a plurality of bitline contacts 146, and an information storage unit 190.

The substrate 100 may be a silicon (Si) or silicon-on-insulator (SOI) substrate. In an implementation, the substrate 100 may include silicon germanium, silicon germanium-on-insulator (SGOI), indium antimonide, a lead telluride compound, indium arsenide, indium nitride, gallium arsenide, or gallium antimonide. As used herein, the term “or” is not necessarily an exclusive term, e.g., “A or B” would include A, B, or A and B.

The cell device isolation film 105 may be in the substrate 100. The cell device isolation film 105 may have a shallow trench isolation (STI) structure with excellent device isolation characteristics. The cell device isolation film 105 may define the cell active regions ACT in a memory cell region.

The cell active regions ACT, defined by the cell device isolation film 105, may have an elongated island shape with both short and long axes, as illustrated in FIGS. 1 and 2. The cell active regions ACT may have a diagonal shape, forming an angle of less than 90 degrees with respect to the wordlines WL, which are formed in the cell device isolation film 105. The cell active regions ACT may also have a diagonal shape, forming an angle of less than 90 degrees with respect to the bitlines BL, which are in the cell device isolation film 105.

The cell device isolation film 105 may include, e.g., a silicon oxide film, a silicon nitride film, or a silicon oxynitride film.

In an implementation, the cell device isolation film 105 may be a single insulating film. In an implementation, the cell device isolation film 105 may be either a single insulating film or as a stack of multiple insulating films, depending on the spacing between the cell active regions ACT.

In an implementation, as illustrated in FIG. 3, the top surfaces of the cell device isolation film 105 and the substrate 100 may be on the same plane. The height of the top surface of the cell device isolation film 105 depicted in FIG. 3 may differ from the height of the top surface of the cell device isolation film 105 depicted in FIG. 4, due to variations in the manufacturing process.

The cell gate structures 110 may be in the substrate 100 and the cell device isolation film 105. The cell gate structures 110 may be formed across the cell device isolation film 105 and the cell active regions ACT, which are defined by the cell device isolation film 105.

The cell gate structures 110 may include cell gate trenches 110T, a cell gate insulating layer 111, cell gate electrodes 112, a first gate dielectric film 113, a second gate dielectric film 114, and a cell gate capping film 114 and may further include a barrier layer 115.

In an implementation, the cell gate electrodes 112 may correspond to the wordlines WL. In an implementation, the cell gate electrodes 112 may be the wordlines WL of FIG. 1.

In an implementation, as depicted in FIG. 5, the cell gate trenches 110T may be relatively deep in the cell device isolation film 105 and relatively shallow in the cell active regions ACT. The bottom surfaces of the wordlines WL may be curved. In an implementation, the depth of the cell gate trenches 110T may be greater in the cell device isolation film 105 than in the cell active regions ACT.

The cell gate trenches 110T may include first areas A1, which are in the substrate 100, and second areas A2, which are on the first areas A1. The second areas A2 may be closer to the top surface of the substrate 100 compared to the first areas A1, in the fourth direction DR4.

The cell gate insulating layer 111 may extend along the sidewalls and bottom surfaces of each of the cell gate trenches 110T. The cell gate insulating layer 111 may extend along at least parts of the profiles of the cell gate trenches 110T. In an implementation, the sidewalls and bottom surfaces of the cell gate trenches 110T may also be referred to as the inner sidewalls of the cell gate trenches 110T.

The cell gate insulating layer 111 may include, e.g., silicon oxide, silicon nitride, silicon oxynitride, or a high-k material with a greater dielectric constant than silicon oxide. The high-k material may include, e.g., boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof.

The first gate dielectric film 113 may be on the sidewalls of the cell gate insulating layer 111 in each of the first areas A1 of the cell gate trenches 110T. The top surface of the first gate dielectric film 113 may be on the same plane as the top surface of the first gate electrode layer 112A.

The second gate dielectric film 114 may be on the sidewalls of the cell gate insulating layer 111 in each of the second areas A2 of the cell gate trenches 110T. The top surface of the second gate dielectric film 114 may be on the same plane as the top surface of the cell gate insulating layer 111.

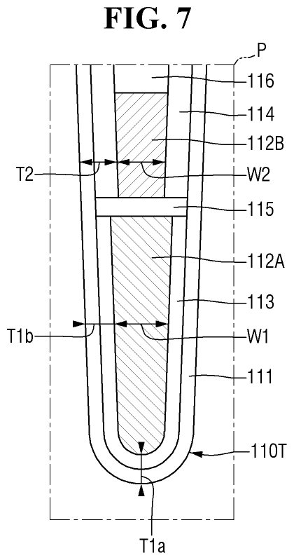

Referring to FIG. 7, in relation to the sidewalls of the cell gate trenches 110T, a sum T2 of the thicknesses of the cell gate insulating layer 111 and the second gate dielectric film 114 may be greater than a sum T1b of the thicknesses of the cell gate insulating layer 111 and the first gate dielectric film 113. The sum T2 of the thicknesses of the cell gate insulating layer 111 and the second gate dielectric film 114 from the sidewalls of the cell gate trenches 110T may be greater than a sum T1a of the thicknesses of the cell gate insulating layer 111 and the first gate dielectric film 113 from the bottom surfaces of the cell gate trenches 110T.

In an implementation, the sum T2 of the thicknesses of the cell gate insulating layer 111 and the second gate dielectric film 114 may be 45 Å or greater, and the sum T1a of the thicknesses of the cell gate insulating layer 111 and the first gate dielectric film 113 may be 35 Å to 45 Å.

In relation to the sidewalls of the cell gate trenches 110T, the thickness of the second gate dielectric film 114 may be greater than the thickness of the first gate dielectric film 113. The thickness of the second gate dielectric film 114 from the sidewalls of the cell gate trenches 110T may be greater than the thickness of the first gate dielectric film 113 from the bottom surfaces of the cell gate trenches 110T.

In an implementation, the first gate dielectric film 113 may include a high-k material with a greater dielectric constant than silicon oxide, and the second gate dielectric film 114 may include a dielectric material with a dielectric constant less than silicon oxide.

The first gate dielectric film 113 may include HfSiO₂, HfSiON, or AlO. The second gate dielectric film 114 may include a dielectric material with a dielectric constant less than the first gate dielectric film 113. In an implementation, the second gate dielectric film 114 may include silicon oxide (SiO₂) or a dielectric material with a dielectric constant less than SiO₂. In an implementation, the second gate dielectric film 114 may include a porous silicon oxide. The second gate dielectric film 114 may include a porous silicate such as SiCOH.

In an implementation, the second gate dielectric film 114 may include a dielectric material with a dielectric constant greater than silicon oxide.

The use of the first gate dielectric film 113 may help improve insulation breakdown characteristics and increase the current near the channel regions by preventing damage to the lower portion of the cell gate insulating layer 111. However, this could also increase the likelihood of gate-induced drain leakage (GIDL) as a leakage current to the drain regions.

Meanwhile, the use of the second gate dielectric film 114 may help mitigate the electric field above the cell gate trenches 110T, thereby reducing GIDL and preventing degradation of refresh time characteristics.

The cell gate electrodes 112 may be on the cell gate insulating layer 111. The cell gate electrodes 112 may at least partially fill the cell gate trenches 110T.

The cell gate electrodes 112 may include a first gate electrode layer 112A and a second gate electrode layer 112B, which is on the first gate electrode layer 112A. The first gate electrode layer 112A may be on the sidewalls of the first gate dielectric film 113 in each of the first areas A1 of the cell gate trenches 110T. The second gate electrode layer 112B may be on the sidewalls of the second gate dielectric film 114 in each of the second areas A2 of the cell gate trenches 110T.

In an implementation, the thickness of the second gate dielectric film 114 may be greater than the thickness of the first gate dielectric film 113, and a width W2 of the second gate electrode layer 112 may be less than a width W1 of the first gate electrode layer 112A.

The second gate electrode layer 112B may not be in contact with the first gate dielectric film 113.

The first gate electrode layer 112A may include a metal, a metal alloy, or a conductive metal nitride. In an implementation, the first gate electrode layer 112A may include titanium nitride. In an implementation, the second gate electrode layer 112B may include a conductive material such as polysilicon.

In an implementation, the first gate electrode layer 112A and the second gate electrode layer 112B may include a work function control material. In an implementation, the work function of the first gate electrode layer 112A may differ from the work function of the second gate electrode layer 112B.

The barrier layer 115 may be between the first gate dielectric film 113 and the second gate dielectric film 114.

The top surface of the barrier layer 115 may be in contact with the bottom surfaces of the second gate dielectric film 114 and the second gate electrode layer 112B. The bottom surface of the barrier layer 115 may be in contact with the top surfaces of the first gate dielectric film 113 and the first gate electrode layer 112A.

In an implementation, the barrier layer 115 may include titanium nitride, silicon nitride, tungsten oxide, or silicon oxide.

The use of the barrier layer 115 may help prevent the first gate electric dielectric film 113 and the second gate electrode layer 112B from being in contact with each other, thereby effectively preventing Fermi level pinning.

A cell gate capping film 116 may be on the second gate electrode layer 112B and the sidewalls of the second gate dielectric film 114. The cell gate capping film 116 may fill the remaining areas of the cell gate trenches 110T after the formation of the cell gate electrodes 112 and the second gate dielectric film 114. At least part of the top surface of the second gate dielectric film 114 may be on the same plane as the top surface of the cell gate capping film 116.

The cell gate capping film 116 may include, e.g., silicon nitride (SiN), silicon oxynitride (SiON), SiO₂, silicon carbonitride (SiCN), silicon oxycarbonitride (SiOCN), or a combination thereof.

In an implementation, as illustrated in FIG. 4, the top surface of the cell gate capping film 116 may be on the same plane as the top surface of the cell device isolation film 105.

Referring to FIG. 5, impurity-doped regions may be on at least one side of each of the cell gate structures 110. The impurity-doped regions may be source/drain regions of transistors. The impurity-doped regions may be in storage connection portions 103b and bitline connection portions 103a of FIG. 2.

In an implementation, referring to FIG. 2, transistors including the wordlines WL, the bitline connection portions 103a, and the storage connection portions 103b may be n-type metal-oxide semiconductor (NMOS) transistors, and the storage connection portions 103b and the bitline connection portions 103a may be regions doped with n-type impurities, e.g., phosphorus (P), arsenic (As), antimony (Sb), or bismuth (Bi). In an implementation, the transistors including the wordlines WL, the bitline connection portions 103a, and the storage connection portions 103b may be p-type metal-oxide semiconductor (PMOS) transistors, and the storage connection portions 103b and the bitline connection portions 103a may be regions doped with p-type impurities such as boron (B).

The bitline structures 140ST may include cell conductive lines 140, a cell line capping film 144, and bitline spacers 150.

The cell conductive lines 140 may be on the substrate 100 and the cell device isolation film 105 with the cell gate structures 110 thereon. The cell conductive lines 140 may intersect the cell device isolation film 105 and the cell active regions ACT, which are defined by the cell device isolation film 105. The cell conductive lines 140 may interest the cell gate structures 110. The cell conductive lines 140 may correspond to the bitlines BL. In an implementation, the cell conductive lines 140 may be the bitlines BL of FIG. 1.

The cell conductive lines 140 may include, e.g., a semiconductor material doped with impurities, a conductive silicide compound, a conductive metal nitride, a two-dimensional (2D) material, a metal, or a metal alloy. The 2D material may be a metallic material or a semiconductor material. The 2D material may include a 2D allotrope or a 2D compound, e.g., graphene, molybdenum disulfide (MoS₂), molybdenum diselenide (MoSe₂), tungsten diselenide (WSe₂), or tungsten disulfide (WS₂).

In an implementation, the cell conductive lines 140 may be single films. In an implementation, the cell conductive lines 140 may include stacks of multiple conductive films.

The cell line capping film 144 may be on the cell conductive lines 140. The cell line capping film 144 may extend in the second direction DR2 along the top surfaces of the cell conductive lines 140. The cell line capping film 144 may include, e.g., a silicon nitride film, a silicon oxynitride film, a silicon carbonitride film, or a silicon oxycarbonitride film.

The cell line capping film 144 may include a silicon nitride film. In an implementation, as illustrated in the drawings, the cell line capping film 144 may be a single film.

The bitline spacers 150 may be on the sidewalls of the cell conductive lines 140 and the sidewalls of the cell line capping film 144. The bitline spacers 150 may extend in the second direction DR2.

In an implementation, as illustrated in the drawings, the bitline spacers 150 may be single films. In an implementation, the bitline spacers 150 may have a multilayered structure. The bitline spacers 150 may include, e.g., silicon oxide, silicon nitride, SiON, SiOCN, air, or a combination thereof.

A cell insulating film 130 may be on the substrate 100 and the cell device isolation film 105. In an implementation, the cell insulating film 130 may be on parts of the substrate 100 where the bitline contacts 146 and storage contacts 120 are not formed and on the top surface of the cell device isolation film 105. The cell insulating film 130 may be between the substrate 100 and the cell conductive lines 140 and between the cell device isolation film 105 and the cell conductive lines 140.

In an implementation, as illustrated in the drawings, the cell insulating film 130 may be a single film, or the cell insulating film 130 may be a multifilm including first and second cell insulating films 131 and 132. In an implementation, the first cell insulating film 131 may include a silicon oxide film, and the second cell insulating film 132 may include a silicon nitride film. In an implementation, the cell insulating film 130 may be a silicon oxide film, a silicon nitride film, or a triple film including a silicon oxide film.

The bitline contacts 146 may be between the cell conductive lines 140 and the substrate 100. The cell conductive lines 140 may be on the bitline contacts 146.

The bitline contacts 146 may be between the bitline connection portions 103a of the cell active regions ACT and the cell conductive lines 140. The bitline contacts 146 may electrically connect the cell conductive lines 140 and the substrate 100. The bitline contacts 146 may be connected to the bitline connection portions 103a.

The bitline contacts 146 may include top surfaces that are connected to the cell conductive lines 140. In an implementation, as illustrated in the drawings, the width of the bitline contacts 146, measured in the first direction DR1, may be uniform in a direction away from the top surfaces of the bitline contacts 146.

The bitline contacts 146 may correspond to the direct contacts DC. The bitline contacts 146 may include, e.g., a semiconductor material doped with impurities, a conductive metal silicide, a conductive metal nitride, a conductive metal oxide, a metal, or a metal alloy.

The bitline spacers 150 may be on the substrate 100 and the cell device isolation film 105, on some of the cell conductive lines 140 where the bitline contacts 146 are formed. The bitline spacers 150 may be on the sidewalls of the cell conductive lines 140, the sidewalls of the cell line capping film 144, and the sidewalls of the bitline contacts 146.

The bitline spacers 150 may be on the cell insulating film 130, in other cell conductive lines 140 where the bitline contacts 146 are not formed. The bitline spacers 150 may be on the sidewalls of the cell conductive lines 140 and the sidewalls of the cell line capping film 144.

Fence patterns 170 may be on the substrate 100 and the cell device isolation film 105. The fence patterns 170 may overlap with the cell gate structures 110, which may be in the substrate 100 and the cell device isolation film 105.

The fence patterns 170 may be between the bitline structures 140ST, which extend in the second direction DR2. The fence patterns 170 may include, e.g., silicon oxide, silicon nitride, silicon oxynitride, or a combination thereof.

The storage contacts 120 may be between cell conductive lines 140 that are adjacent to each other in the first direction DR1. The storage contacts 120 may be on both sides of each of the cell conductive lines 140. In an implementation, the storage contacts 120 may be between the bitline structures 140ST. The storage contacts 120 may be between fence patterns 170 that are adjacent to each other in the second direction DR2.

The storage contacts 120 may overlap with the substrate 100 and the cell device isolation film 105 between the cell conductive lines 140. The storage contacts 120 may be connected to the cell active regions ACT. In an implementation, the storage contacts 120 may correspond to the storage connection portions 103b. In an implementation, the storage contacts 120 may correspond to the buried contacts BC of FIG. 1.

The storage contacts 120 may include, e.g., a semiconductor material doped with impurities, a conductive silicide compound, a conductive metal nitride, or a metal.

Storage pads 160 may be on the storage contacts 120. The storage pads 160 may be electrically connected to the storage contacts 120. The storage pads 160 may be connected to the storage connection portions 103b. In an implementation, the storage pads 160 may correspond to the landing pads LP.

The storage pads 160 may overlap with parts of the top surfaces of the bitline structures 140ST. The storage pads 160 may include, e.g., a conductive metal nitride, a conductive metal carbide, a metal, or a metal alloy.

A pad isolation insulating film 180 may be on the storage pads 160 and the bitline structures 140ST. In an implementation, the pad isolation insulating film 180 may be on the cell line capping film 144. The pad isolation insulating film 180 may define the storage pads 160, which form a plurality of isolated regions. The pad isolation insulating film 180 may not cover the top surfaces of the storage pads 160. In an implementation, in relation to the top surface of the substrate 100, the height of the top surfaces of the storage pads 160 may be the same as the height of the top surface of the pad isolation insulating film 180.

The pad isolation insulating film 180 may include an insulating material and may electrically isolate the storage pads 160. In an implementation, the pad isolation insulating film 180 may include, e.g., a silicon oxide film, a silicon nitride film, a silicon oxynitride film, a silicon oxycarbonitride film, or a silicon carbonitride film.

An etch stopper film 292 may be on the top surfaces of the storage pads 160 and the top surface of the pad isolation insulating film 180. The etch stopper film 292 may include, e.g., SiN, SiCN, SiOCN, SiOC, or SiBN.

The information storage unit 190 may be on the storage pads 160. The information storage unit 190 may be connected to the storage pads 160. The information storage unit 190 may be partially in the etch stopper film 292.

The information storage unit 190 may include, e.g., capacitors. The information storage unit 190 may include the lower electrodes 191, a capacitor dielectric film 192, and an upper electrode 193. In an implementation, the upper electrode 193 may include a plate upper electrode having a plate shape.

The lower electrodes 191 may be on the storage pads 160. The lower electrodes 191 may have, e.g., a pillar shape.

The capacitor dielectric film 192 may be on the lower electrodes 191. The capacitor dielectric film 192 may be along the profiles of the lower electrodes 191. The upper electrode 193 may be on the capacitor dielectric film 192. The upper electrode 193 may surround the outer sidewalls of each of the lower electrodes 191. In an implementation, as illustrated in the drawings, the upper electrode 193 may be, e.g., a single film.

The lower electrodes 191 and the upper electrode 193 may include, e.g., a doped semiconductor material, a conductive metal nitride (e.g., titanium nitride, tantalum nitride, niobium nitride, or tungsten nitride), a metal (e.g., ruthenium, iridium, titanium, or tantalum), or a conductive metal oxide (e.g., iridium oxide or niobium oxide).

The capacitor dielectric film 192 may include, e.g., silicon oxide, silicon nitride, silicon oxynitride, a high-k material, or a combination thereof. The capacitor dielectric film 192 may have a structure where which zirconium oxide, aluminum oxide, and zirconium oxide are sequentially stacked. The capacitor dielectric film 192 may include a dielectric film containing hafnium (Hf). The capacitor dielectric film 192 may have a stacked film structure where a ferroelectric material film and a paraelectric material film are stacked.

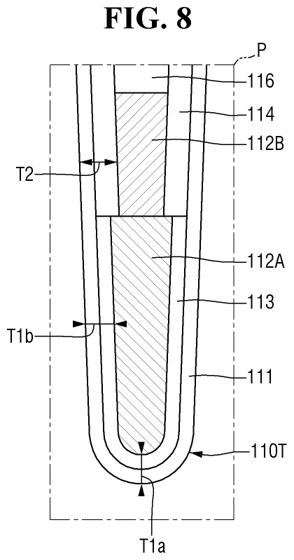

FIGS. 8 through 11 are other exemplary enlarged cross-sectional views of part P of FIG. 6. The embodiment of FIGS. 8 through 11 will hereinafter be described, highlighting the differences with the embodiment of FIGS. 1 through 7.

Referring to FIG. 8, a barrier layer may not be between first and second gate dielectric films 113 and 114. In an implementation, in relation to the inner sidewalls of a cell gate trench 110T, a sum T2 of the thicknesses of a cell gate insulating film 111 and the second gate dielectric film 114 may be greater than a thickness T1 of the thicknesses of the cell gate insulating layer 111 and the first gate dielectric film 113. A second gate electrode layer 112B may not be in contact with the first gate dielectric film 113.

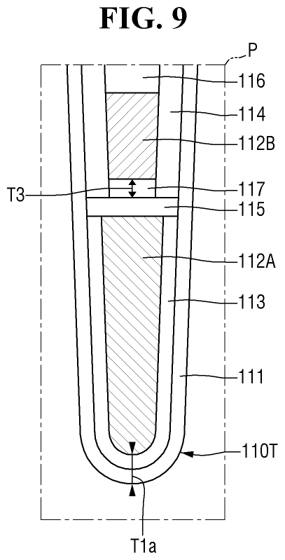

Referring to FIG. 9, a cell gate structure 110 may further include an inserted insulating layer 117, which may be between a barrier layer 115 and a second gate electrode layer 112B. The width of the inserted insulating layer 117 may be less than the width of the barrier layer 115.

The inserted insulating layer 117 may include the same material as a second gate dielectric film 114. In an implementation, as illustrated in FIG. 9, the interface between the inserted insulating layer 117 and the second gate dielectric film 114 may be distinct. In an implementation, the inserted insulating layer 117 and the second gate dielectric film 114 may be integrally formed together.

In an implementation, the inserted insulating layer 117 may include a material with a smaller dielectric constant than silicon oxide and the first gate dielectric film 113. In an implementation, the inserted insulating layer 117 may include a material with a greater dielectric constant than silicon oxide. In an implementation, a thickness T3 of the inserted insulating layer 117 may be 10 Å or less.

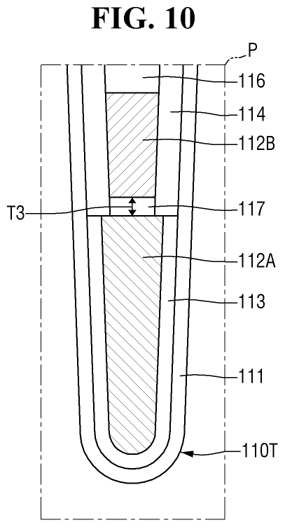

Referring to FIG. 10, a cell gate structure 110 may not include a barrier layer 115. In an implementation, an inserted insulating layer 117 may be between first and second gate electrode layers 112A and 112B and may be in contact with the first and second gate electrode layers 112A and 112B. In an implementation, a thickness T3 of the inserted insulating layer 117 may be 10 Å or less.

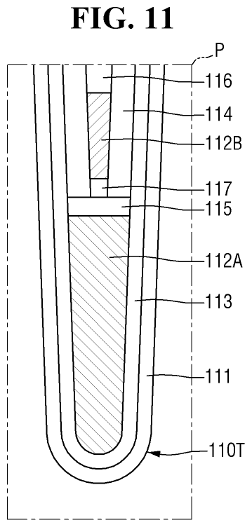

Referring to FIG. 11, a first gate dielectric film 113 may be further disposed between a cell gate insulating layer 111 and a second gate dielectric film 114. In an implementation, the first gate dielectric film 113 may be further disposed in a second area (“A2” of FIG. 6). The top surface of the first gate dielectric film 114 may be on the same plane as the top surface of the cell gate insulating layer 111. In an implementation, an upper portion of the first gate dielectric film 113 may not be removed, and may remain.

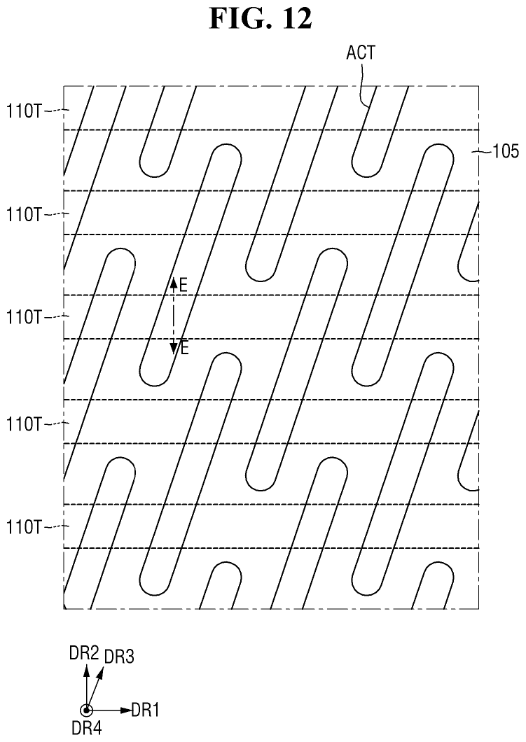

FIGS. 12 through 18 are layout views or cross-sectional views of stages in a method of fabricating a semiconductor memory device according to some embodiments of the present disclosure. The embodiment of FIGS. 12 through 18 will hereinafter be described, highlighting the differences with the embodiments of FIGS. 1 through 11.

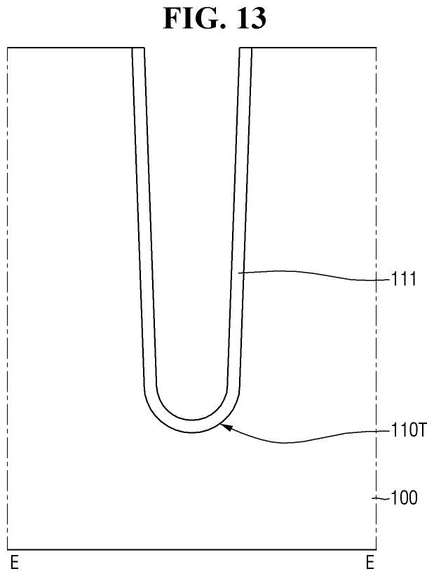

FIG. 12 is a layout view illustrating a stage in a method of method of fabricating a semiconductor memory device according to some embodiments of the present disclosure. FIGS. 13 through 18 are cross-sectional views taken along line E-E of FIG. 12.

Referring to FIG. 12, a cell device isolation film 105 may be formed in a substrate 100. The cell device isolation film 105 may have a shallow trench isolation (STI) structure. The cell device isolation film 105 may define cell active regions ACT in a memory cell region.

The cell device isolation film 105 may include, e.g., a silicon oxide film, a silicon nitride film, or a silicon oxynitride film.

In an implementation, as illustrated in the drawings, the cell device isolation film 105 may be formed as a single insulating film. In an implementation, the cell device isolation film 105 may be formed either as a single insulating film or as a stack of multiple insulating films.

Referring to FIGS. 12 and 13, first trenches 110T may be formed in the substrate 100 and the cell device isolation film 105. In an implementation, the first trenches 110T may be formed by forming a mask pattern on the substrate 100 and etching the substrate 100 using the mask pattern as an etching mask. The first trenches 110T may extend in a first direction DR1. The first trenches 110T may be formed across the cell device isolation film 105 and the cell active regions ACT, which are defined by the cell device isolation film 105.

A cell gate insulating layer 111 may be formed in the first trenches 110T and on the top surface of the substrate 100. The cell gate insulating layer 111 may be formed by an atomic layer deposition (ALD) or chemical vapor deposition (CVD) process. The cell gate insulating layer 111 may be formed along the sidewalls and bottom surface of each of the first trenches 110T. The cell gate insulating layer 111 may include silicon oxide.

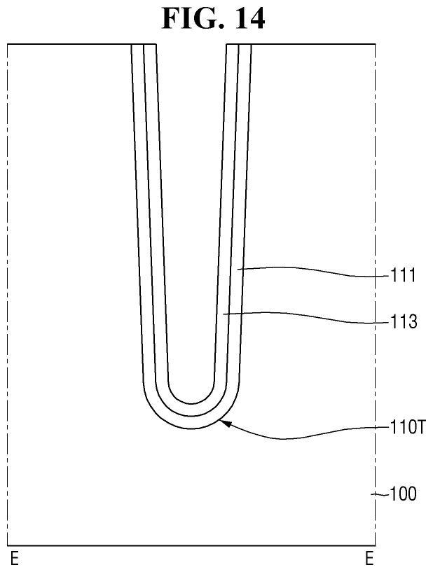

Referring to FIG. 14, a first gate dielectric film 113 may be formed on the cell gate insulating layer 111. The first gate dielectric film 113 may be formed along the sidewalls and bottom surface of each of the first trenches 110T, filling the inside of the first trenches 110T.

The first gate dielectric film 113 may include, e.g., HfSiO₂, HfSiON, or AlO.

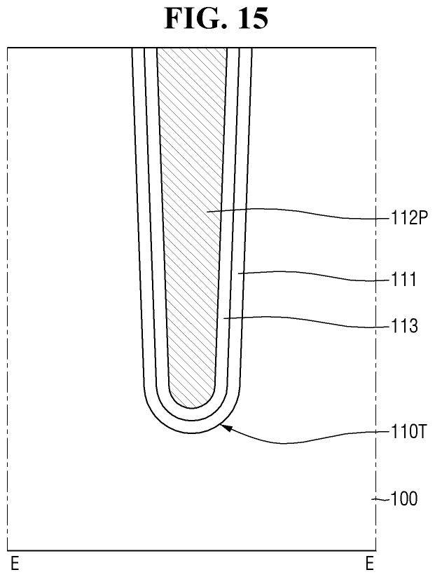

Referring to FIG. 15, a first pre-cell gate electrode 112P may be formed on the first gate dielectric film 113.

A conductive material may be deposited on the first gate dielectric film 113. The conductive material may fill the first trenches 110T. The deposition of the conductive material may be performed by a CVD process. The conductive material may include, e.g., a metal, a metal alloy, or a conductive metal nitride.

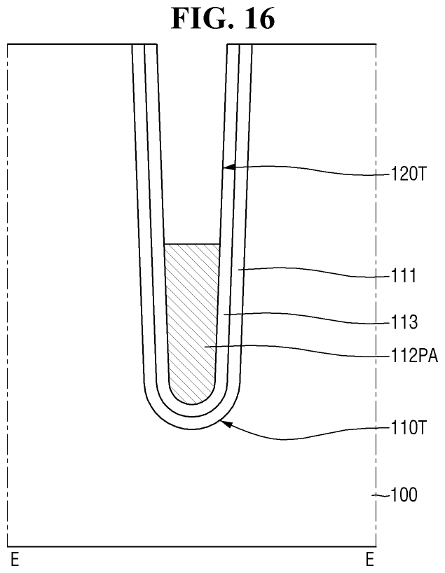

Referring to FIG. 16, a lower pre-cell gate electrode 112PA may be formed by partially etching the first pre-cell gate electrode 112P. In an implementation, the conductive material may be etched by an etch-back process.

The etch-back process may be performed using the etching selectivity between the metal material present in the first per-cell gate electrode 112P and the oxide present in the cell gate insulating layer 111 and the first gate dielectric film 113.

As a result of the etch-back process, a second trench 120T may be formed on the lower pre-cell gate electrode 112PA and the first gate dielectric film 113.

Thereafter, heat treatment may be performed on the lower pre-cell gate electrode 112PA. As a result of the heat treatment, impurities present in the lower pre-cell gate electrode 112PA may be removed.

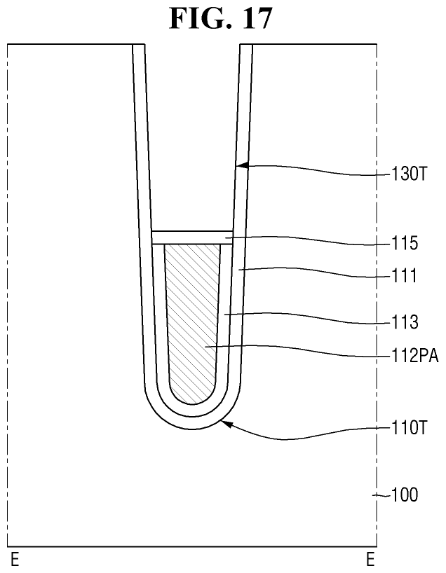

Referring to FIG. 17, at least part of the first gate dielectric film 113 that is beyond the top surface of the lower pre-cell gate electrode 112PA may be removed. Thereafter, a barrier layer 115 may be formed on the top surface of the lower pre-cell gate electrode 112PA.

Accordingly, a third trench 130T, which exposes parts of the sidewalls of the cell gate insulating layer 111 and the top surface of the barrier layer 115, may be formed.

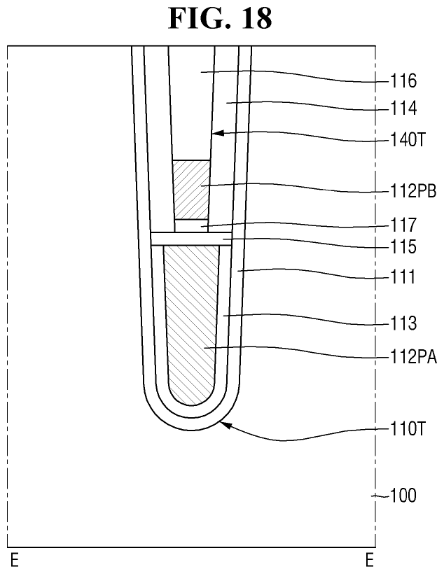

Referring to FIG. 18, a second gate dielectric film 114 and an inserted insulating layer 117 may be formed along the sidewalls and bottom surface of the third trench 130T.

In an implementation, the inserted insulating layer 117 may include a material with a smaller dielectric constant than silicon oxide and the first gate dielectric film 113. In an implementation, the inserted insulating layer 117 may include a material with a greater dielectric constant than silicon oxide.

The second gate dielectric film 114 may be formed only on the sidewalls of the third trench 130T, but not on the bottom surface of the third trench 130T. In an implementation, part of the second gate dielectric film 114 that is formed on the bottom surface of the third trench 130T may be removed. In an implementation, as illustrated in FIG. 9, the second gate dielectric film 114 may be formed on the sidewalls of the third trench 130T, and the inserted insulating layer 117 may be formed on the bottom surface of the third trench 130T.

Thereafter, a second pre-cell gate electrode may be deposited on the second gate dielectric film 114. In an implementation, the second pre-cell gate electrode may include a conductive material such as polysilicon.

An upper pre-cell gate electrode 112PB may be formed by partially etching the second pre-cell gate electrode. In an implementation, the conductive material may be etched by an etch-back process.

As a result of the etch-back process, a fourth trench 140T may be formed on the upper pre-cell gate electrode 112PB and the second gate dielectric film 114.

Thereafter, heat treatment may be performed on the upper pre-cell gate electrode 112PB.

Thereafter, a cell gate capping film 116 may be formed on the upper pre-cell gate electrode 112PB and the second gate dielectric film 114, filling the fourth trench 114T. In an implementation, the cell gate capping film 116 may be formed by forming a capping film on the entire surface of the substrate 100 and performing a planarization process. The cell gate capping film 116 may include, e.g., a silicon nitride film, a silicon oxide film, or a silicon oxynitride film. In this process, part of the cell gate insulating layer 111 that covers the substrate 100 may be removed.

As a result of the planarization process, a cell gate structure 110 may be formed. The cell gate structure 110 may include a cell gate trench 110T, a cell gate insulating layer 111, a cell gate electrode 112, a first gate dielectric film 113, a second gate dielectric film 114, a barrier layer 115, an inserted insulating layer 117, and a cell gate capping film 116. The cell gate electrode 112 may correspond to a wordline WL.

Thereafter, a bitline structure 140ST, which may extend in a second direction DR2, may be formed on the substrate 100. The bitline structure 140ST may include a cell conductive line 140, a cell line capping film 144, and bitline spacers 150.

A storage contact 120, a storage pad 160, and an information storage unit 190 may be formed on storage connection portions 103b of each of the cell active regions ACT. The information storage unit 190 may include lower electrodes 191, a capacitor dielectric film 192, and an upper electrode 193.

By way of summation and review, the reduction in pitch could result in an increase in gate-induced drain leakage (GIDL), which could negatively impact the refresh characteristics of the devices. To address this, technologies have been developed that utilize heterogeneous materials with different work functions as the constituents of the gate electrodes to suppress leakage current and precisely control the threshold voltage of the gate electrodes.

One or more embodiments may provide a semiconductor memory device capable of improving reliability and performance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a substrate including a device isolation film, which defines active regions; and
cell gate structures in trenches, which include first areas in the substrate and second areas on the first areas, the cell gate structures extending to intersect the active regions,
wherein:
each of the cell gate structures includes a cell gate insulating layer, which extends along inner sidewalls of its corresponding trenches, a first gate dielectric film, which is on sidewalls of the cell gate insulating layer, in a first area of the corresponding trench, a second gate dielectric film, which is on the sidewalls of the cell gate insulating layer, in a second area of the corresponding trench, and a cell gate electrode structure, which includes a first gate electrode layer on sidewalls of the first gate dielectric film in the first area of the corresponding trench and a second gate electrode layer on sidewalls of the second gate dielectric film in the second area of the corresponding trench, and
in relation to the inner sidewalls of the corresponding trench, the second gate dielectric film has a greater thickness than the first gate dielectric film.

2. The semiconductor memory device as claimed in claim 1, wherein the second gate electrode layer and the first gate dielectric film are not in contact with each other.

3. The semiconductor memory device as claimed in claim 1, wherein a top surface of the second gate dielectric film is on the same plane as a top surface of the cell gate insulating layer.

4. The semiconductor memory device as claimed in claim 1, wherein:
each of the gate structures further includes an inserted insulating layer, which is between the first and second gate electrode layers, and
the inserted insulating layer includes the same material as the second gate dielectric film.

5. The semiconductor memory device as claimed in claim 1, wherein:
the first gate dielectric film is further disposed between the sidewalls of the cell gate insulating layer and the sidewalls of the second gate dielectric film, and
a top surface of the first gate dielectric film is on the same plane as a top surface of the cell gate insulating layer.

6. The semiconductor memory device as claimed in claim 1, wherein the second gate dielectric film includes a material with a smaller dielectric constant than the first gate dielectric film.

7. The semiconductor memory device as claimed in claim 1, wherein each of the gate structures further includes a barrier layer, which is between the first and second gate dielectric films.

8. The semiconductor memory device as claimed in claim 7, wherein:
a top surface of the barrier layer is in contact with bottom surfaces of the second gate dielectric film and the second gate electrode layer, and
a bottom surface of the barrier layer is in contact with top surfaces of the first gate dielectric film and the first gate electrode layer.

9. The semiconductor memory device as claimed in claim 7, wherein the barrier layer includes titanium nitride, silicon nitride, tungsten oxide, or silicon oxide.

10. The semiconductor memory device as claimed in claim 1, wherein each of the gate structures further includes a capping film, which is on the second gate electrode layer.

11. The semiconductor memory device as claimed in claim 1, further comprising:
first source/drain regions and second source/drain regions in the active regions;
bitline structures on the substrate and connected to the first source/drain regions; and
an information storage unit on the substrate and connected to the second source/drain regions.

12. A semiconductor memory device, comprising:
a substrate including a device isolation film, which defines active regions; and
gate structures in trenches, which include first areas in the substrate and second areas on the first areas, the gate structures extending to intersect the active regions,
wherein:
each of the gate structures includes a first gate insulating layer, which extends along sidewalls and a bottom surface of its corresponding trenches, a first gate dielectric film, which is on sidewalls of the first gate insulating layer, in a first area of the corresponding trench, a second gate dielectric film, which is on the sidewalls of the first gate insulating layer, in a second area of the corresponding trench, a barrier layer between the first and second gate dielectric films, a gate electrode structure, which includes a first gate electrode layer on sidewalls of the first gate dielectric film in the first area of the corresponding trench and a second gate electrode layer on sidewalls of the second gate dielectric film in the second area of the corresponding trench, and a capping film, which is on the second gate electrode layer, and
the barrier layer is in contact with a bottom surface of the second gate dielectric film and a top surface of the first gate dielectric film.

13. The semiconductor memory device as claimed in claim 12, wherein:
a thickness of the second gate dielectric film from the sidewalls of the corresponding trench is greater than a thickness of the first gate dielectric film from the bottom surface of the corresponding trench, and
a width of the second gate electrode layer is less than a width of the first gate electrode layer.

14. The semiconductor memory device as claimed in claim 13, wherein:
a sum of thicknesses of the first gate insulating layer and the second gate dielectric film is 45 Å or greater, and
a sum of thicknesses of the first gate insulating layer and the first gate dielectric film is 35 Å to 45 Å.

15. The semiconductor memory device as claimed in claim 12, wherein at least part of a top surface of the second gate dielectric film is on the same plane as a top surface of the capping film.

16. The semiconductor memory device as claimed in claim 12, wherein the first gate dielectric film includes a material with a smaller dielectric constant than the second gate dielectric film.

17. The semiconductor memory device as claimed in claim 12, wherein:
each of the gate structures further includes an inserted insulating layer, which is between the barrier layer and the second gate electrode layer, and
a width of the inserted insulating layer is less than a width of the barrier layer.

18. The semiconductor memory device as claimed in claim 17, wherein a thickness of the inserted insulating layer is 10 Å or less.

19. The semiconductor memory device as claimed in claim 12, wherein:
the first gate dielectric film is further disposed between the sidewalls of the first gate insulating layer and the sidewalls of the second gate dielectric film, and
a top surface of the first gate dielectric film is on the same plane as a top surface of the first gate insulating layer.

20. A semiconductor memory device, comprising:
a substrate including a device isolation film, which defines active regions; and
gate structures in trenches, which include first areas in the substrate and second areas on the first areas, the gate structures extending to intersect the active regions,
wherein:
each of the gate structures includes a first gate insulating layer, which extends along sidewalls and a bottom surface of its corresponding trenches, a first gate dielectric film, which is on sidewalls of the first gate insulating layer, in a first area of the corresponding trench, a second gate dielectric film, which is on the sidewalls of the first gate insulating layer, in a second area of the corresponding trench, a barrier layer between the first and second gate dielectric films, a gate electrode structure, which includes a first gate electrode layer on sidewalls of the first gate dielectric film in the first area of the corresponding trench and a second gate electrode layer on sidewalls of the second gate dielectric film in the second area of the corresponding trench, an inserted insulating layer, which is between the barrier layer and the second gate electrode layer, and a capping film, which is on the second gate electrode layer, and
in relation to the sidewalls of the corresponding trench, the second gate dielectric film has a greater thickness than the first gate dielectric film.
